(19) United States
(12) Patent Application Publication
(10) Pub. No.: US 2026/0060010 A1
(43) Pub. Date: Feb. 26, 2026

(54) THRESHOLD SWITCHING VOLATILE MEMRISTOR AND OSCILLATORY CIRCUIT USING SAME

(71) Applicant: National Cheng Kung University, Tainan City (TW)

(72) Inventors: Jen-Sue CHEN, Tainan City (TW); Shuai-Ming CHEN, Tainan City (TW)

(73) Assignee: National Cheng Kung University, Tainan City (TW)

(21) Appl. No.: 18/902,228

(22) Filed: Sep. 30, 2024

(30) Foreign Application Priority Data
Aug. 21, 2024 (TW) 113131490

(51) Int. Cl. H10N 70/00; G06N 3/065; H10B 63/00; H10N 70/20

(52) U.S. Cl. CPC H10N 70/8833; G06N 3/065; H10B 63/82; H10N 70/20

(57) ABSTRACT

A threshold switching volatile memristor includes a first metal layer, an active layer, a matching metal layer, and a second metal layer. The active layer is on the first metal layer and is made of niobium oxide. The matching metal layer is on the active layer and is made of niobium. The second metal layer is on the matching metal layer, where a thickness ratio of the active layer to the matching metal layer is 2 to 3.5, and a thickness of the matching metal layer is less than 40 nanometers. Within oscillatory circuit, The threshold switching volatile memristor has a negative differential resistance characteristic, and when a current is applied, reverse appears after a voltage reverses reaches a threshold voltage, and a spike signal is measured at an output end. Thus, it is suitable for spike neural networks.

### CROSS-REFERENCE TO RELATED APPLICATION

This non-provisional application claims priority under 35 U.S.C. § 119 (a) to patent application No. 113131490 filed in Taiwan, R.O.C. on Aug. 21, 2024, the entire contents of which are hereby incorporated by reference.

### BACKGROUND

### Technical Field

The present invention relates to the field of electronic circuits, and in particular, to a threshold switching volatile memristor and an oscillatory circuit using the same.

### Related Art

Artificial intelligence (AI) technology is undoubtedly the biggest driving force for the next generation of industrial technologies, and its wide range of applications may also greatly change the existing ecology of science and technology, which will lead to a new wave of high-performance computing demands.

With the vigorous development of artificial intelligence in recent years, neural network computing is an emerging field that has attracted tremendous attention recently, where a spike neural network (SNN) has been widely studied by scientists in terms of programming due to its low energy consumption, parallel computing, and asynchronous computing. Inspired by mimicking brain-like ultra-low power consumption and large-scale parallel computing, the spike neural network forms a massive neural circuit composed of neurons and synapses. The spike neural network conveys information in the form of spikes, and achieves the effect of network learning and decision making via the transmission of spikes, thereby providing faster and lower energy-consuming information processing capabilities.

In terms of hardware implementation, if a basic computing unit of the spike neural network is constructed with a conventional complementary metal oxide semiconductor (CMOS), a huge and complex circuitry is required. For example, the CMOS is used as the architecture of imitation synapses and imitation neurons. Usually, four CMOS-based components and two comparators need to be provided in an imitation synapse unit, while an imitation neuron unit needs to be provided with two comparators, a phase change controller, and a pulse encoder. Due to the complex composition of circuits and elements, the overall power consumption and costs are high.

### SUMMARY

In order to provide convenience for implementing a spike neural network and reduce costs, here, a threshold switching volatile memristor is provided. The threshold switching volatile memristor includes a first metal layer, an active layer, a matching metal layer, and a second metal layer. The active layer is on the first metal layer and is made of niobium oxide (NbOₓ). The matching metal layer is on the active layer and is made of niobium (Nb). The second metal layer is on the matching metal layer, where a thickness ratio of the active layer to the matching metal layer is 2 to 3.5, and a thickness of the matching metal layer is less than 40 nanometers. The threshold switching volatile memristor has a negative differential resistance characteristic, and when a current is applied to the threshold switching volatile memristor, a voltage-current curve of the threshold switching volatile memristor reverses after a voltage reaches a threshold voltage.

In some embodiments, the first metal layer and the second metal layer are made of platinum (Pt). More specifically, in some embodiments, a thickness ratio of the first metal layer to the matching metal layer is 4 to 5.

Further, in some embodiments, a thickness ratio of the second metal layer to the matching metal layer is 4 to 5.

In some embodiments, the threshold switching volatile memristor further includes a second matching metal layer, where the second matching metal layer is between the active layer and the first metal layer, and a thickness of the second matching metal layer is less than or equal to the thickness of the matching metal layer.

Here, an oscillatory circuit is further provided. The oscillatory circuit includes an input end, a first resistor, a ground end, a threshold switching volatile memristor, a second resistor, a capacitor, a first output end, and a second output end. The input end is connected in series to the first resistor, and provides an input voltage. The threshold switching volatile memristor is connected to the input end. The second resistor is connected in series to the threshold switching volatile memristor, and is connected to the ground end. The capacitor is connected in parallel to the threshold switching volatile memristor and the second resistor, and is connected to the first resistor and the ground end. The first output end is between the first resistor and the threshold switching volatile memristor, and outputs a first output voltage. The second output end is between the threshold switching volatile memristor and the second resistor, and outputs a second output voltage. The threshold switching volatile memristor includes a first metal layer, an active layer, a matching metal layer, and a second metal layer. The active layer is on the first metal layer and is made of niobium oxide (NbOₓ), the matching metal layer is on the active layer and is made of niobium (Nb), and the second metal layer is on the matching metal layer, where a thickness ratio of the active layer to the matching metal layer is 2 to 3.5, and a thickness of the matching metal layer is less than 40 nanometers. The threshold switching volatile memristor exhibits a negative differential resistance characteristic. When a current source applies a current sweep to the memristor, the current-voltage curve reverses after the voltage reaches a threshold voltage.

In some embodiments, the first metal layer and the second metal layer are made of platinum (Pt). More specifically, in some embodiments, a thickness ratio of the first metal layer to the matching metal layer is 4 to 5. Further, in some embodiments, a thickness ratio of the second metal layer to the matching metal layer is 4 to 5.

In some embodiments, the threshold switching volatile memristor further includes a second matching metal layer, where the second matching metal layer is between the active layer and the first metal layer, and a thickness of the second matching metal layer is less than or equal to the thickness of the matching metal layer.

In some embodiments, the oscillatory circuit further includes a dynamic memristor, where after being connected in parallel to the first resistor, the dynamic memristor is connected to a node where the threshold switching volatile memristor and the second resistor are connected in parallel to the capacitor.

In some embodiments, the oscillatory circuit further includes a dynamic memristor, where the dynamic memristor is connected in parallel to the capacitor, the threshold switching volatile memristor, and the second resistor.

As stated in the previous embodiments, the niobium oxide, which is the material of the active layer in the threshold switching volatile memristor, exhibits the negative differential resistance characteristic, and when the input voltage reaches certain magnitude, the output end will measure a spike signal, and then the threshold switching volatile memristor can be controlled by either voltage or current to output the spike signal. By the threshold switching volatile memristor and the oscillatory circuit applying the same, elements for implementing the spike neural network can be greatly simplified, thus reducing the overall costs, increasing the overall reaction speed and achieving more energy-saving effect.

### BRIEF DESCRIPTION OF THE DRAWINGS

FIG. 1 is a cross-sectional view of an embodiment of a threshold switching volatile memristor.

FIG. 2 is a voltage-current characteristic curve of a threshold switching volatile memristor.

FIG. 3 is a cross-sectional view of another embodiment of a threshold switching volatile memristor.

FIG. 4A to FIG. 4C are a method for fabricating a threshold switching volatile memristor and voltage-current characteristic curves under the condition of compliance current.

FIG. 5 is a voltage-current characteristic curve of a dynamic memristor under the stimulation of a pulse square wave of a fixed voltage.

FIG. 6 is a circuit diagram of a first embodiment of an oscillatory circuit applying a threshold switching volatile memristor.

FIG. 7 is a voltage-time curve graph of a first embodiment.

FIG. 8 is a circuit diagram of a second embodiment of an oscillatory circuit applying a threshold switching volatile memristor.

FIG. 9 is a voltage-time curve graph of a second embodiment.

FIG. 10 is a circuit diagram of a third embodiment of an oscillatory circuit applying a threshold switching volatile memristor.

FIG. 11 is a voltage-time curve graph of a third embodiment.

### DETAILED DESCRIPTION

In the following description, the terms “first”, “second”, and “third” are only used to distinguish one element, component, region, layer or part from another element, component, region, layer or part, and do not indicate their necessary order. Furthermore, relative terms such as “lower” and “upper”, “inner” and “outer” may be used herein to describe the relationship of one element and another element. It should be understood that the relative terms are intended to include different orientations of an apparatus other than those shown in the drawings. For example, if the apparatus in one drawing is turned over, the element described as being on the “lower” side of the other element will be oriented on the “upper” sides of the other element. This only represents a relative orientation relationship, instead of an absolute orientation relationship.

In the drawings, the widths of some elements, regions, etc. are enlarged for clarity. Throughout this specification, like reference numerals refer to like elements. It should be understood that when, for example, an element is referred to as being “on” or “connected to” another element, it may be directly on or connected to another element, or an intermediate element may also be present. On the contrary, when an element is referred to as “directly on another element” or “directly connected to” another element, there is no intermediate element.

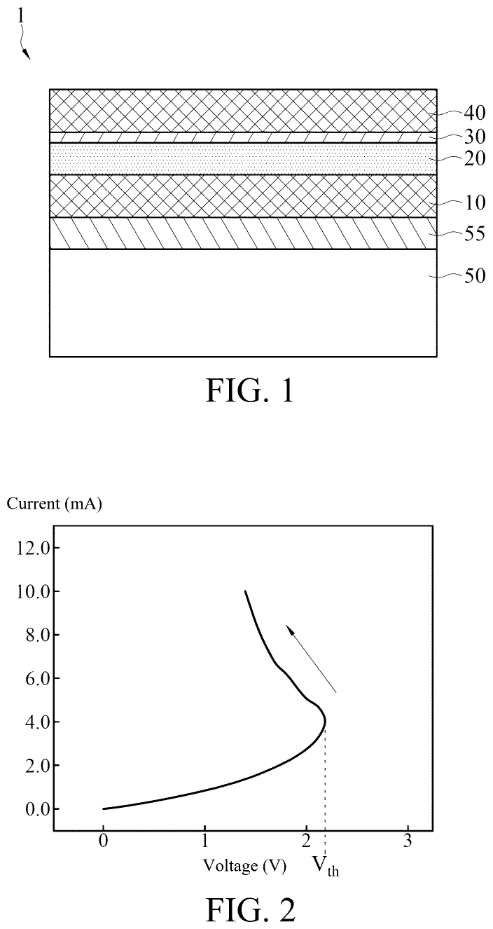

FIG. 1 is a cross-sectional view of an embodiment of a threshold switching volatile memristor. FIG. 2 is a voltage-current characteristic curve of a threshold switching volatile memristor. As shown in FIG. 1, the threshold switching volatile memristor 1 includes a first metal layer 10, an active layer 20, a matching metal layer 30, and a second metal layer 40. The active layer 20 is on the first metal layer 10 and is made of niobium oxide (NbOₓ). The matching metal layer 30 is on the active layer 20 and is made of niobium (Nb). The second metal layer 40 is on the matching metal layer 30, where the thickness ratio of the active layer 20 to the matching metal layer 30 is 2 to 3.5, and the thickness of the matching metal layer 30 is less than 40 nanometers. Furthermore, the threshold switching volatile memristor 1 is formed on a p-type doped silicon substrate 50. In addition, a dielectric layer 55, e.g., a silicon dioxide (SiO₂) layer, may be provided between the p-type doped silicon substrate 50 and the first metal layer 10.

As shown in FIG. 2, the voltage-current characteristic curve of the threshold switching volatile memristor 1 exhibits a negative differential resistance characteristic. This is due to the Joule heating effect of the niobium oxide (NbOₓ) of the active layer 20 combined with the Poole-Frank conduction mechanism. When a bias voltage is applied to the threshold switching volatile memristor 1, Joule heating causes the temperature of the threshold switching volatile memristor 1 to increase, and then, based on the Poole-Frank conduction mechanism, the higher the temperature, the higher the conductance value. Further, the conductance value increases, which in turn causes a current value increases, and generates more heat. This cycle makes the conductance value rise sharply, resulting in the negative differential resistance characteristic. In addition, more specifically, the threshold switching volatile memristor 1 exhibits an S-shaped negative differential resistance characteristic. When a current is applied to the threshold switching volatile memristor 1, the voltage current curve of the threshold switching volatile memristor reverses after a voltage reaches a threshold voltage Vₜₕ.

Referring again to FIG. 1, although presented only by way of example in the drawing, it is plotted to an actual scale. More specifically, in some embodiments, the thickness ratio of the first metal layer 10 to the matching metal layer 30 is 4 to 5.

Further, in some embodiments, the thickness ratio of the second metal layer 40 to the matching metal layer 30 is 4 to 5.

In some embodiments, the first metal layer 10 and the second metal layer 40 are made of platinum (Pt), thus providing stable anti-oxidation properties and avoiding affecting the overall electrical performance. For example, the thicknesses of the first metal layer 10, the active layer 20, the matching metal layer 30, and the second metal layer 40 are 80 nm to 100 nm, 45 nm to 75 nm, 15 nm to 26 nm, and 80 nm to 100 nm, respectively. Preferably, the thicknesses of the first metal layer 10, the active layer 20, the matching metal layer 30, and the second metal layer 40 are 82 nm to 90 nm, 45 nm to 68 nm, 18 nm to 25 nm, and 85 nm to 100 nm, respectively. Here, they are only made at a laboratory level, and with a higher-level technology, they can be scaled in equal proportions.

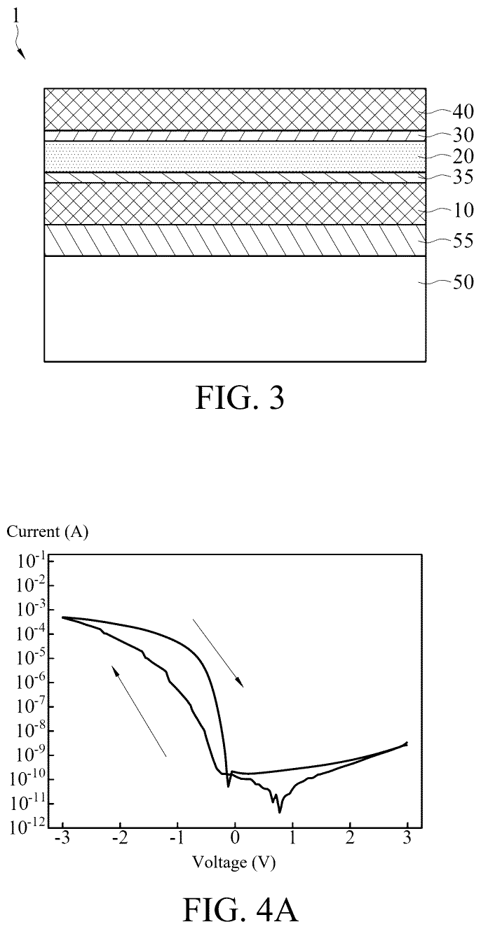

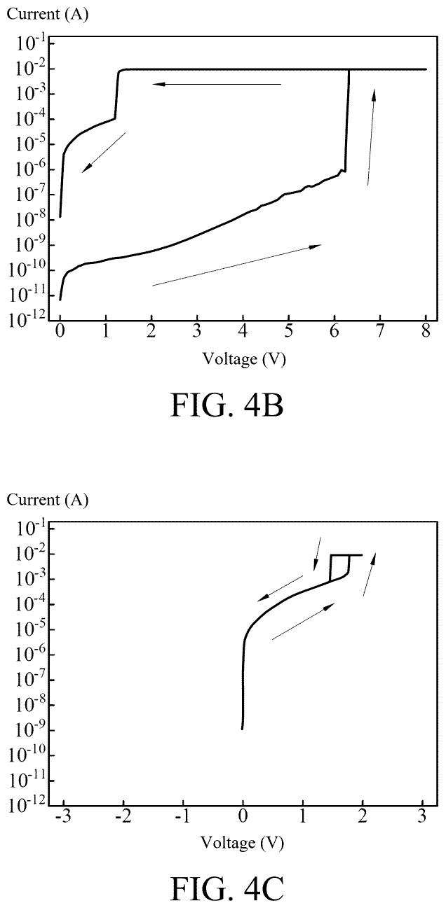

FIG. 3 is a cross-sectional view of another embodiment of a threshold switching volatile memristor. In some embodiments, the threshold switching volatile memristor 1 further includes a second matching metal layer 35. The second matching metal layer 35 is between the active layer 20 and the first metal layer 10. The thickness of the second matching metal layer 35 is less than or equal to the thickness of the matching metal layer 30. It should be noted that under the structure of the second embodiment, the threshold switching volatile memristor itself has the characteristic of threshold switching volatility. However, under the structure of the first embodiment, the characteristic of threshold switching volatility can only be achieved by electro-forming, which will be described in detail with reference to FIG. 4A to FIG. 4C.

FIG. 4A to FIG. 4C are a method for fabricating a threshold switching volatile memristor and voltage-current characteristic curves under the condition of limiting current. The element in FIG. 4C is of the structure of the first embodiment. When the structure is only completed, in a case where the current is limited, a negative bias voltage sweep region exhibits forward hysteresis and the current value will increase during the sweep operation from 3 V to −3V, and then from −3V to 3V. This type of voltage-current configuration is referred to as a “dynamic memristor”, which mainly operates via the volatilization characteristics of a hysteresis window.

Then, as shown in FIG. 4B, for the element with the structure of the first embodiment, a large voltage is applied to change the electrical properties of the element. Here, sweeping is performed from 0V to 8V, and then from 8V to 0V, and it is found that the current value of the element suddenly rises at a specific voltage, so that electro-forming is completed.

As shown in FIG. 4C, the electrical mode of an electro-formed element is completely different from that of the dynamic memristor of FIG. 4A. As shown in FIG. 4C, during the sweeping operation from 0V to 2V, and then 2V to OV, the characteristic of volatile threshold switching similar to that of FIG. 4B is exhibited, thus completing the threshold switching volatile memristor 1. Measurement is performed in a manner of applying a current, and thus, the curve of FIG. 2 may be obtained.

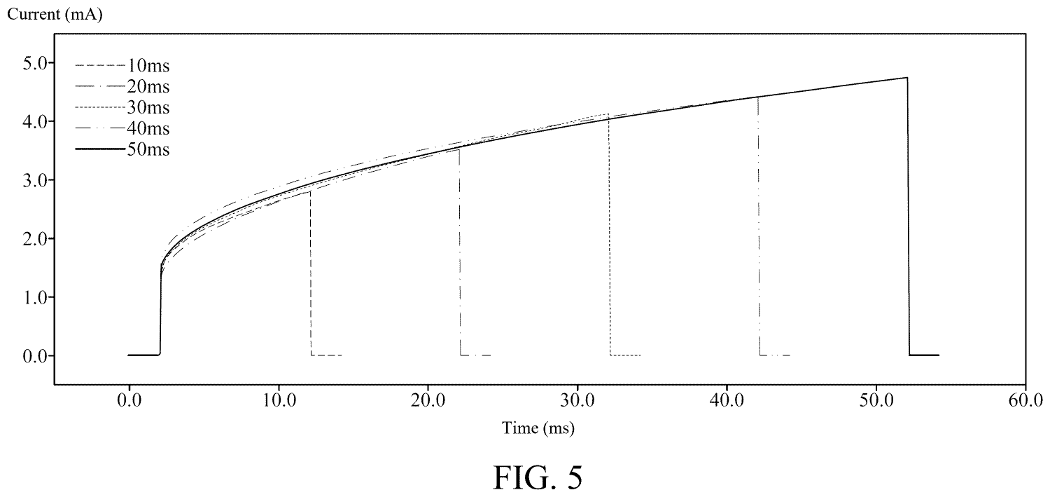

In other words, under the structure of FIG. 1, it can be considered whether electro-forming is performed or not to selectively operate the element in a dynamic memristor mode or a threshold switching volatile memristor mode. Reference may be made to FIG. 5 for the electrical characteristics of the dynamic memristor mode.

FIG. 5 is a voltage-current characteristic curve of a dynamic memristor under the stimulation of a pulse square wave of a fixed voltage. As shown in FIG. 5, the pulse square wave of the fixed voltage is applied to the dynamic memristor, which shows a behavior that the current value gradually increases, and the longer the stimulation time, the higher the current value, that is, the resistance value of the element may gradually decrease. After the stimulation ends, the resistance value may gradually return to its original state. Therefore, the current value during each test may start to ramp up from a similar position.

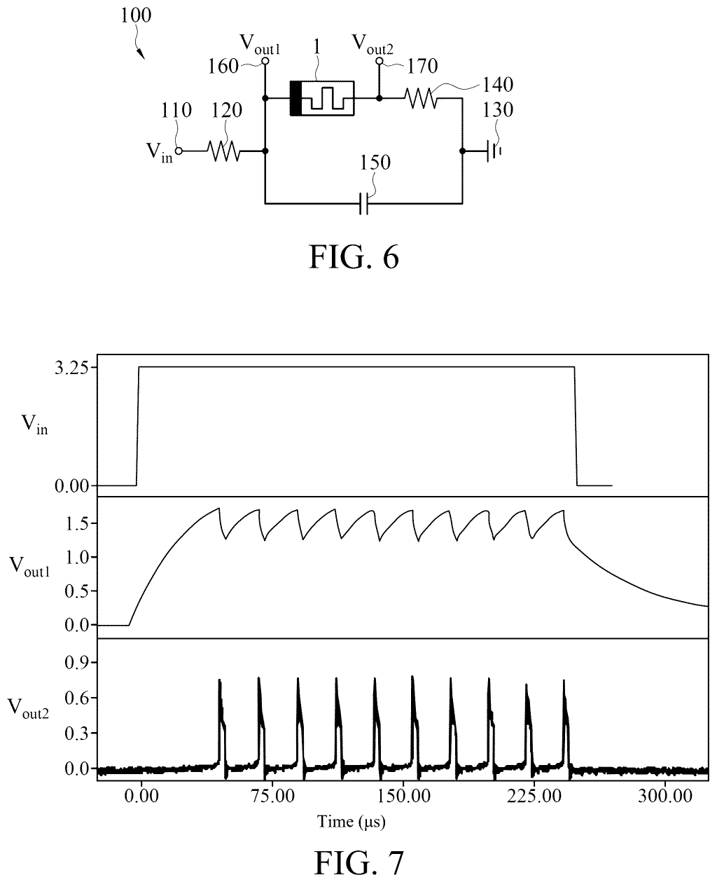

FIG. 6 is a circuit diagram of a first embodiment of an oscillatory circuit applying a threshold switching volatile memristor. FIG. 7 is a voltage-time curve graph of a first embodiment. As shown in FIG. 6, an oscillatory circuit 100 includes an input end 110, a first resistor 120, a ground end 130, a threshold switching volatile memristor 1, a second resistor 140, a capacitor 150, a first output end 160, and a second output end 170. The input end 110 is connected in series to the first resistor 120, and provides an input voltage Vin. The threshold switching volatile memristor 1 is connected to the first resistor 120. The second resistor 140 is connected in series to the ground end 130. The capacitor 150 is connected in parallel to the threshold switching volatile memristor 1 and the second resistor 140, and is connected to the first resistor 120 and the ground end 130. The first output end 160 is between the first resistor 120 and the threshold switching volatile memristor 1, and outputs a first output voltage Vₒᵤₜ₁. The second output end 170 is between the threshold switching volatile memristor 1 and the second resistor 140, and outputs a second output voltage Vₒᵤₜ₂. The material and structure of the threshold switching volatile memristor 1 are as described above, which will not be repeated here.

As shown in FIG. 7, the input voltage in is a square wave. It can be observed that the second output voltage Vₒᵤₜ₂ outputted at the second output end 170 is converted into a spike signal through the process of charging and discharging. Here, by using a threshold switching volatile memristor 1, the oscillatory circuit 100 can be used as an imitation neuron unit of a spike neural network (SNN) with a very small number of electronic components. Further, encoding may be performed using the frequency change of the spike signal.

It is illustrated here that a metal-oxide-metal structure of the threshold switching volatile memristor 1 itself has the equivalent effect of a resistor and parasitic capacitor. In other words, the circuit of FIG. 6 is also an equivalent circuit of the threshold switching volatile memristor 1. The second resistor 140 and the capacitor 150 may also be omitted in order to save the overall costs for constructing the spike neural network. Here, in order to stably and accurately control the spike signal, and to investigate the design of a logic circuit layout, the operation is carried out by additionally adding the second resistor 140 and the capacitor 150.

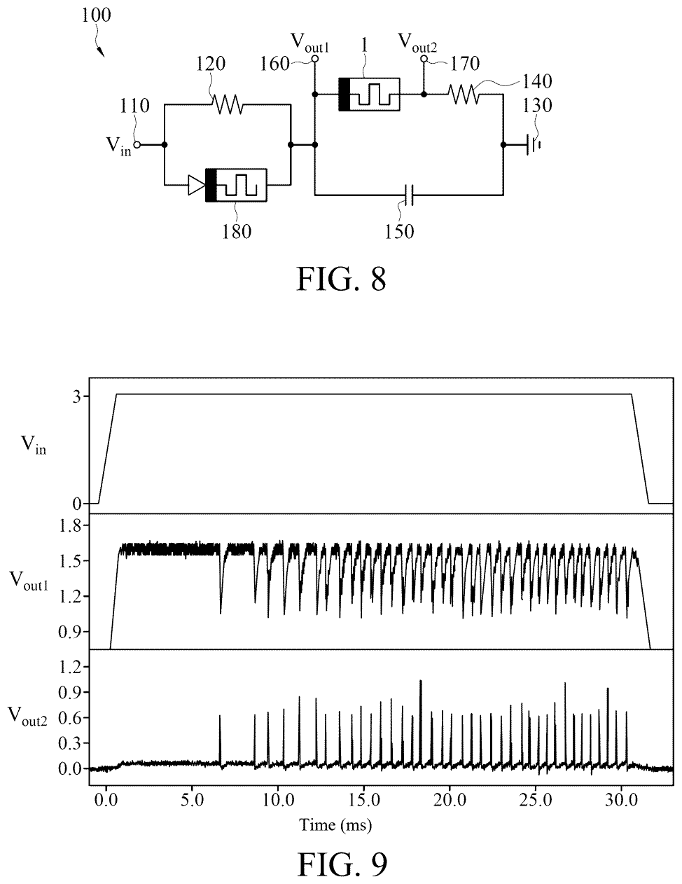

FIG. 8 is a circuit diagram of a second embodiment of an oscillatory circuit applying a threshold switching volatile memristor. FIG. 9 is a voltage-time curve graph of a second embodiment. As shown in FIG. 8, an oscillatory circuit 100 further includes a dynamic memristor 180. It is illustrated here that the dynamic memristor 180 has characteristics similar to those of a diode combined with the threshold switching volatile memristor 1. In the drawing, the oscillatory circuit is represented by symbols of the threshold switching volatile memristor and the diode, and is actually a single element. After being connected in parallel to the first resistor 120, the dynamic memristor 180 is connected to a node where the threshold switching volatile memristor 1 and the second resistor 140 are connected in parallel onto the capacitor 150.

In the bionic design for the human brain, for the same stimulation, the sensitivity can be increased, and the frequency from the spike wave conduction increases, which is referred to as the characteristic of “sensitization”. The voltage-time curve graph presented by combining the dynamic memristor 180 with the oscillatory circuit 100 of the first embodiment is as shown in FIG. 9. It can be seen that under the stimulation of the fixed voltage, the oscillating behavior will become more frequent, and the characteristic of sensitization is presented.

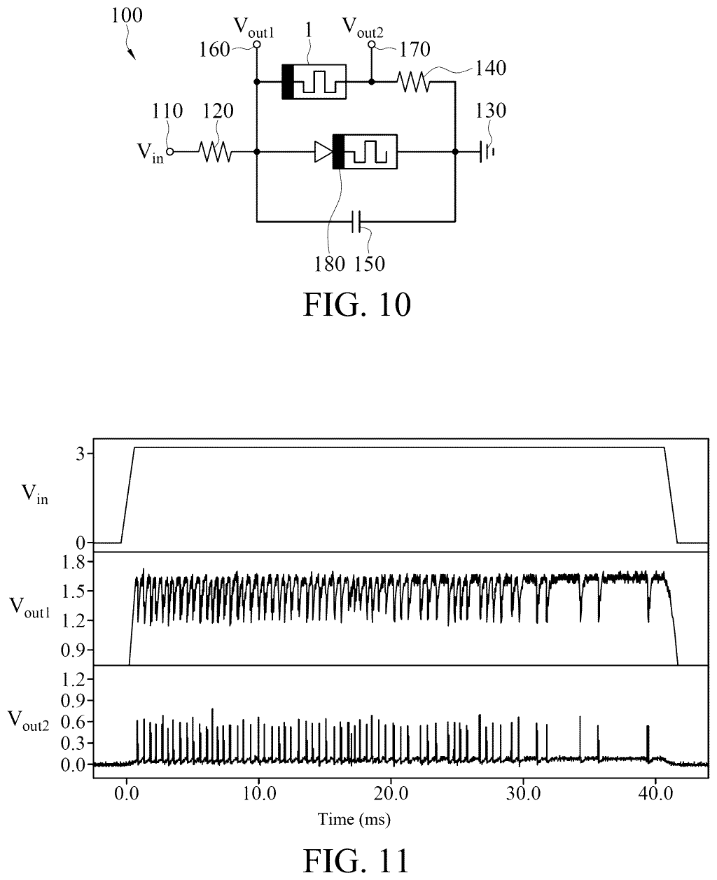

FIG. 10 is a circuit diagram of a third embodiment of an oscillatory circuit applying a threshold switching volatile memristor. FIG. 11 is a voltage-time curve graph of a third embodiment. Here, as shown in FIG. 10 and referring to FIG. 8 at the same time, unlike the second embodiment, the dynamic memristor 180 is connected in parallel to the capacitor 150, the threshold switching volatile memristor 1, and the second resistor 140. As shown in FIG. 11, the characteristic presented here, contrary to the second embodiment, exhibits a state that the frequency of the oscillating behavior is reduced, which is referred to as “passivation”. The circuitry collocation of “sensitization” and “passivation” may be proposed for different reactions as needed, and the efficacy of the spike neural network (SNN) can be further improved.

To sum up, the niobium oxide, which is the material of the active layer 20 in the threshold switching volatile memristor 1, has the negative differential resistance characteristic, and when the input voltage reaches certain magnitude, a spike signal may be measured, and then the threshold switching volatile memristor 1 can be controlled by the voltage or current to output the spike signal. By the threshold switching volatile memristor 1 and the oscillatory circuit 100 applying the same, elements for implementing the spike neural network can be greatly simplified, thus reducing the overall costs, increasing the overall reaction speed and achieving more energy-saving effect.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A threshold switching volatile memristor, comprising:
a first metal layer;
an active layer on the first metal layer and made of niobium oxide (NbOₓ);
a matching metal layer on the active layer and made of niobium (Nb); and
a second metal layer on the matching metal layer, wherein,
a thickness ratio of the active layer to the matching metal layer is 2 to 3.5, and a thickness of the matching metal layer is less than 40 nanometers, wherein the threshold switching volatile memristor has a negative differential resistance characteristic, and when a current is applied to the threshold switching volatile memristor, a voltage-current curve of the threshold switching volatile memristor reverses after a voltage reaches a threshold voltage.

2. The threshold switching volatile memristor according to claim 1, wherein the first metal layer and the second metal layer are made of platinum (Pt).

3. The threshold switching volatile memristor according to claim 2, wherein a thickness ratio of the first metal layer to the matching metal layer is 4 to 5.

4. The threshold switching volatile memristor according to claim 3, wherein a thickness ratio of the second metal layer to the matching metal layer is 4 to 5.

5. The threshold switching volatile memristor according to claim 1, further comprising a second matching metal layer, wherein the second matching metal layer is between the active layer and the first metal layer, and a thickness of the second matching metal layer is less than or equal to the thickness of the matching metal layer.

6. An oscillatory circuit, comprising:
an input end, connected in series to a first resistor, and providing an input voltage;
a ground end;
a threshold switching volatile memristor, connected to the first resistor;
a second resistor, connected in series to the threshold switching volatile memristor, and connected to the ground end;
a capacitor, connected in parallel to the threshold switching volatile memristor and the second resistor, and connected to the first resistor and the ground end;
a first output end between the first resistor and the threshold switching volatile memristor, and outputting a first output voltage; and
a second output end between the threshold switching volatile memristor and the second resistor, and outputting a second output voltage, wherein,
the threshold switching volatile memristor comprises a first metal layer, an active layer, a matching metal layer, and a second metal layer, the active layer is on the first metal layer and is made of niobium oxide (NbOₓ), the matching metal layer is on the active layer and is made of niobium (Nb), the second metal layer is on the matching metal layer, a thickness ratio of the active layer to the matching metal layer is 2 to 3.5, and a thickness of the matching metal layer is less than 40 nanometers, wherein the threshold switching volatile memristor has a negative differential resistance characteristic, and when a current is applied to the threshold switching volatile memristor, a voltage-current curve of the threshold switching volatile memristor reverses after a voltage reaches a threshold voltage.

7. The oscillatory circuit according to claim 6, wherein the first metal layer and the second metal layer are made of platinum (Pt).

8. The oscillatory circuit according to claim 7, wherein a thickness ratio of the first metal layer to the matching metal layer is 4 to 5.

9. The oscillatory circuit according to claim 8, wherein a thickness ratio of the second metal layer to the matching metal layer is 4 to 5.

10. The oscillatory circuit according to claim 6, further comprising a second matching metal layer, wherein the second matching metal layer is between the active layer and the first metal layer, and a thickness of the second matching metal layer is less than or equal to the thickness of the matching metal layer.

11. The oscillatory circuit according to claim 6, further comprising a dynamic memristor, wherein after being connected in parallel to the first resistor, the dynamic memristor is connected to a node where the threshold switching volatile memristor and the second resistor are connected in parallel to the capacitor.

12. The oscillatory circuit according to claim 6, further comprising a dynamic memristor, wherein the dynamic memristor is connected in parallel to the capacitor, the threshold switching volatile memristor, and the second resistor.
